(19) United States
(12) Patent Application Publication
(10) Pub. No.: US 2002/0098664 A1
(43) Pub. Date: Jul. 25, 2002

(54) Method of producing SOI materials

(76) Inventor: Ziwei Fang, San Jose, CA (US)

Correspondence Address: Gary L. Loser, Esq., Vice President and General Counsel, Varian Semiconductor Equipment Associates, Inc., 35 Dory Road, Gloucester, MA, 01930, US

(21) Appl. No.: 09/767,787

(22) Filed: Jan. 23, 2001

(51) Int. Cl. H01L 21/20

(52) U.S. Cl. 438/480

(57) ABSTRACT

The present invention provides a method of producing SOI materials. The method involves implanting oxygen ions in a silicon substrate to form an implanted region at a relatively shallow depth using a plasma implantation step. The substrate is then annealed at elevated temperatures to convert the implanted region to an insulating layer which may be beneath a thin silicon seed layer. A silicon layer is grown, preferably epitaxially, on the thin silicon seed layer to provide a high quality single crystal in which devices may be formed. The SOI materials are suitable for use as substrates in a wide variety of SOI applications.

### FIELD OF THE INVENTION

The invention relates generally to semiconductor processing and, more particularly, to a method of producing silicon on insulator materials.

### BACKGROUND OF THE INVENTION

Silicon on insulator (SOI) materials have a silicon layer formed upon an insulator material. SOI materials can be used as semiconductor substrates in microelectronic applications. Semiconductor devices may be formed, for example, in the silicon layer. Amongst other advantages, SOI substrates may effectively isolate devices and circuits formed upon the same substrate from one another. Furthermore, SOI substrates also present new possibilities for device design.

Wafer bonding is a conventional technique for producing SOI materials which has been described, for example, in U.S. Pat. No. 5,710,057. Wafer bonding techniques generally involve bonding a first silicon wafer to a second silicon wafer, which includes an insulating layer on its surface, to form an SOI structure. However, wafer bonding techniques may be cumbersome and time-consuming.

Oxygen implantation techniques may also be used to produce SOI materials. Such techniques generally involve an ion implantation step in which oxygen ions are accelerated towards a silicon substrate at a selected implantation energy. The ions are implanted over a desired depth and, upon heating, react with the silicon substrate to form a buried silicon oxide layer (SiO₂). The silicon oxide layer buried beneath the silicon layer, thus, forms the SOI structure. However, in order to implant a sufficient concentration of oxygen atoms to form the buried silicon oxide layer, ion implantation techniques need to use a relatively large dose. The dose is proportional to the beam current multiplied by the implant time. Because ion implantation techniques cannot utilize high beam currents, long implant times are typically required to achieve the appropriate dose to form implanted oxygen regions of sufficient concentration. The long implant times result in relatively low throughputs (i.e., the number of wafers processed per unit time) for SOI processes using ion implantation techniques.

To meet the demands of current commercial semiconductor processes, it is desirable for processes to have a high wafer throughput. The conventional techniques described herein for producing SOI materials may be limited in their ability to meet the throughput demands of commercial semiconductor processes. Accordingly, there is a need for a method of producing high quality SOI materials at a high throughput.

### SUMMARY OF THE INVENTION

The present invention provides a method of producing SOI materials. The method involves implanting oxygen ions in a silicon substrate to form an implanted region at a relatively shallow depth using a plasma implantation step. The substrate is then annealed at elevated temperatures to convert the implanted region to an insulating layer which may be beneath a thin silicon seed layer. A silicon layer is grown, preferably epitaxially, on the thin silicon seed layer to form a region in which devices may be formed. The SOI materials are suitable for use as substrates in a wide variety of SOI applications.

In one aspect, the invention provides a method of producing an SOI material. The method includes implanting oxygen in a substrate using plasma implantation to form an implanted region, annealing the substrate to form an insulating layer comprising implanted oxygen, and growing a silicon layer over the insulating layer to produce an SOI material.

In another aspect, the invention provides a method of producing an SOI material. The method includes implanting oxygen in a substrate using plasma implantation to form an implanted region, annealing the substrate to cause a reaction between implanted oxygen and the substrate to form an insulating layer, and epitaxially growing a silicon layer over the insulating layer to produce an SOI material.

Among other advantages, the invention provides a method for producing SOI materials at a high throughput. The high throughput is achieved by utilizing relatively short plasma implantation and epitaxial growth steps instead of a relatively long ion implant step. Plasma implantation may be utilized to form the implanted oxygen region because the region is formed at a shallow depth, with the subsequent epitaxial growth step providing sufficient thickness for the silicon device layer. The plasma implantation step may use short implant times to form implanted regions having sufficient oxygen concentration because plasma implantation is not restricted by beam current limitations.

Furthermore, the invention provides SOI materials having low defect densities and contamination levels because the silicon device layer may be grown epitaxially.

Other advantages, aspects and features of the invention will become apparent from the following detailed description of the invention when considered in conjunction with the accompanying drawings.

### BRIEF DESCRIPTION OF THE DRAWINGS

FIG. 1 is a cross section of an SOI wafer produced according to one embodiment of the present invention.

FIG. 2A is a cross section of a substrate used as a starting material according to one embodiment of the present invention.

FIG. 2B is a cross section of the substrate after a plasma implantation step according to one embodiment of the present invention.

FIG. 2C is a cross section of the substrate after an annealing step according to one embodiment of the present invention.

FIG. 2D is a cross section of the substrate after an etching step according to one embodiment of the present invention.

FIG. 2E is a cross section of the substrate after an epitaxial growth step according to one embodiment of the present invention.

FIG. 3A is a depth profile of implanted oxygen prior to the annealing step according to one embodiment of the present invention.

FIG. 3B is a depth profile of implanted oxygen after the annealing step according to one embodiment of the present invention.

### DETAILED DESCRIPTION

The invention provides a method for producing silicon on insulator (SOI) materials. The method involves forming a buried insulating layer at a relatively shallow depth within a silicon substrate using a plasma implantation step followed by an annealing step. A silicon layer is then grown, for example epitaxially, upon the substrate to form an SOI material. Such materials may be used as semiconductor wafers which may be further processed to form semiconductor devices in the epitaxial silicon layer.

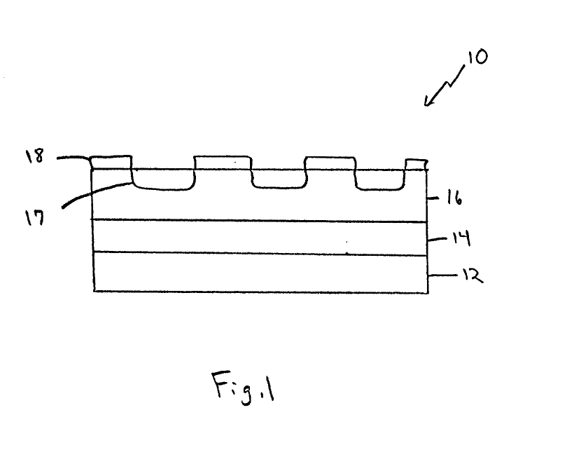

Referring to FIG. 1, an SOI wafer 10 is shown according to one embodiment of the present invention. Wafer 10 includes a substrate 12, an insulating layer 14 formed upon the substrate, and a silicon layer 16 formed upon the insulating layer 14. As described further below, silicon layer 16 includes a region of high quality single crystal material, such as an epitaxial layer, suitable for use as a substrate for semiconductor devices. When devices are formed, wafer 10 may include conventional features such as doped regions 17 within silicon layer 16, additional layers 18 on silicon layer 16 (e.g., oxide layers, metallization layers), and the like.

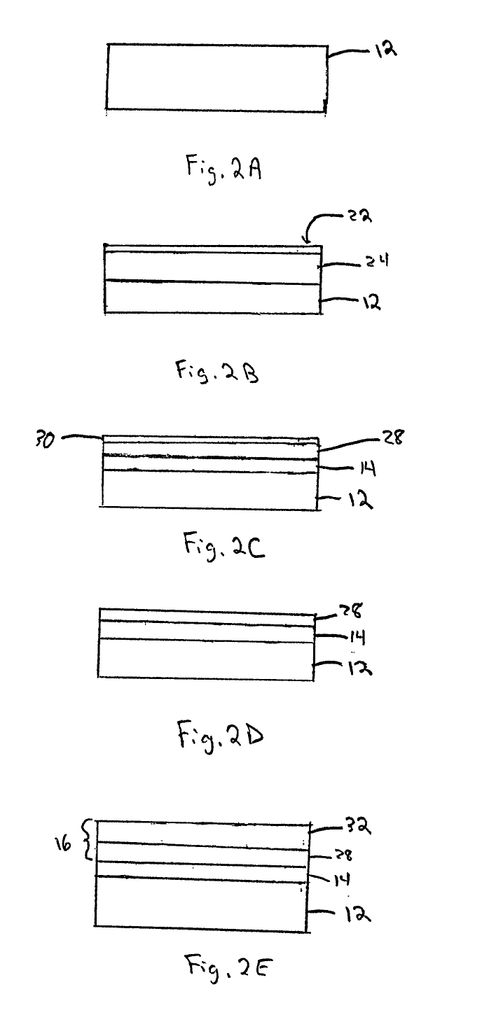

FIGS. 2A-2E are cross sections of SOI wafer 10 after different processing steps according to one illustrative method of the present invention.

FIG. 2A shows a substrate 12 which is used as a starting material in the illustrative method. Substrate 12 may be any of the type used in semiconductor processing such as a silicon substrate. Exemplary dimensions of substrate 12 include a diameter of between about 200 mm and about 300 mm, and a thickness of between about 600 microns and about 700 microns. It should be understood that substrates having other dimensions may also be used.

The illustrative method includes a step of implanting oxygen into substrate 12 to form an implanted region 24, as shown in FIG. 2B, using a plasma implantation step. During plasma implantation, substrate 12 is typically supported in a process chamber under vacuum conditions. Plasma implantation involves generating a plasma, which includes positive ions, and accelerating the ions toward a front surface 22 of substrate 12. Any suitable plasma implantation process known in the art may be used. Such processes may generate the plasma, for example, using pulsed high voltage, ICP (Inductive Coupled Plasma) and ECR (Electron Cyclitron Residence) methods.

Generally, oxygen plasmas may include both O₂⁺ ions and O⁺ions. Techniques known in the art can be employed to control the ratio of O₂⁺ions to O⁺ ions in the plasma. Such techniques may involve the adjustment of one or more process parameters including electrode geometry, input power, gas pressure and magnetic field strength. In some methods, as described further below, it is preferable to have the ratio of O₂⁺/O⁺ approach 1.0 or 0 so that the plasma includes a dominant amount of either O₂⁺ions or O⁺ions. In some cases, the ratio is greater than 0.90 or greater than about 0.95. In other cases, the ratio is less than 0.10 or less than 0.05.

The plasma implantation step advantageously may be performed at relatively short implant times, particularly compared to the time of ion implantation steps in conventional SOI processes. Short implant times are achievable because plasma implantation can provide an appropriate dose by utilizing a high beam current. The short implant times can lead to increases in wafer throughput.

Generally during plasma implantation, the temperature of substrate 12 is controlled by known cooling and/or heating techniques to prevent thermal damage. Typically, the temperature is controlled between about 600° C. and about 700° C. It may be advantageous in certain embodiments to use relatively low implantation energies. Processes that utilize a low implantation energy may reduce cooling requirements which can decrease implant times. In some embodiments, the implantation energy for O⁺ atoms is less than 40 kV, less than 30 kV, or even lower.

FIG. 2B shows a cross section of substrate 12 after the implantation step. Implanted region 24 is formed by the presence of oxygen ions within the lattice structure of substrate 12, for example, at interstitial sites. The oxygen concentration of implanted region 24 varies as a function of the distance away from front surface 22. The concentration depth profile depends upon the processing conditions of the implantation step.

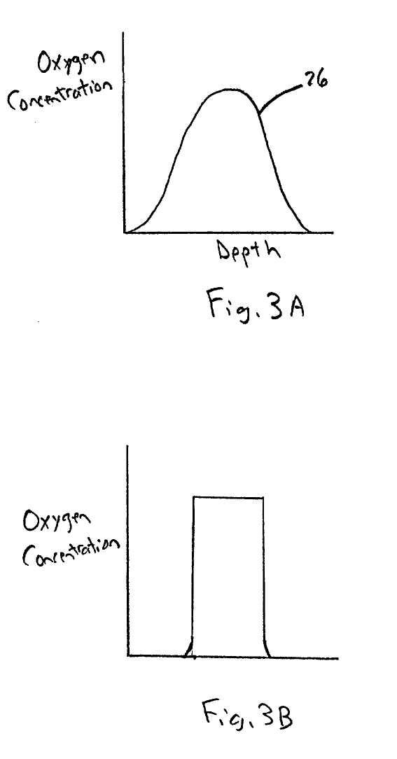

FIG. 3A is a typical depth profile showing the concentration of oxygen ions as a function of depth into substrate 12. The illustrative depth profile includes a dominant single peak 26 which may be preferred in certain embodiments. A single dominant peak, for example, may be advantageous in forming insulating layer 14 having well-defined boundaries at the desired depth. The single peak is representative of an implant process that utilized a dominant amount (e.g., greater than 90% or 95%) of either O₂⁺ ions or O⁺ ions, as described above. In some cases when a dominant peak is present, a minority peak may also be observable.

Peak 26 preferably has a maximum oxygen concentration at a depth of about 500 Angstroms. In certain embodiments, the maximum oxygen concentration occurs at a depth of between about 300 Angstroms and about 800 Angstroms. The maximum oxygen concentration may be between about 10²² atoms/cm³ and about 5×10²² atoms/cm³. However, the specific depth of the maximum oxygen concentration and the maximum oxygen concentration depends upon the particular application and may fall outside the ranges described herein.

After the implantation step, the illustrative method includes an annealing step to form insulating layer 14. FIG. 2C shows the cross section of substrate 12 after annealing. Generally, the wafer is removed from the implantation process chamber and transferred to a furnace for the annealing step. Within the furnace, a large number of wafers may be annealed at once so as not to limit throughput. The annealing step involves heating the wafer to an elevated temperature to form insulating layer 14 (e.g., SiO₂) having well-defined boundaries.

The annealing step causes the implanted oxygen ions to diffuse to regions of high oxygen ion concentration where the oxygen ions react with the substrate to form insulating layer 14. The oxygen atoms diffuse to regions of high concentration because the driving force for the atoms to chemically react with silicon outweighs the driving force which otherwise would cause the atoms to diffuse to regions of low concentration. Consequently, regions with low oxygen ion concentrations (i.e., at the edges of the depth profile) become depleted of oxygen atoms and the depth profile becomes rectangular in shape having a relatively constant implanted oxygen concentration. A typical depth profile resulting from annealing is shown in FIG. 3B.

The temperature and time of the annealing step may be any combination that causes the reaction to occur. The specific annealing conditions will depend upon the particular method. Typically, annealing temperatures are greater than 1200° C. and annealing times are greater than 1 hour. However, other conditions may be utilized in some cases. In certain preferred embodiments, the annealing temperature is greater than about 1350° C. and the annealing time is between about 0.5 hours and 4 hours. As described above, because a large number of wafers may be annealed at once the annealing times do not limit wafer throughput.

The thickness of insulating layer 14 generally depends upon the particular application and can be controlled by implant process conditions. In some embodiments, the thickness is between about 800 Angstroms and about 2000 Angstroms. As a result of the diffusion of oxygen ions, regions above and below insulating layer 14 are, in some cases, substantially free of implanted oxygen ions. In particular, this results in the creation of a thin silicon seed layer 28 above insulating layer 14. In some embodiments, seed layer 28 has a thickness of the less than 100 Angstroms, in some embodiments less than 50 Angstroms, and in some embodiments between about 30 Angstroms and 100 Angstroms. Seed layer 28 is preferably a high quality single crystal silicon layer with a low defect concentration. However, it should be understood that in some embodiments, seed layer 28 may include minor amounts of defects including oxygen ions. As described further below, seed layer 28 facilitates the deposition of a high quality epitaxial layer.

In certain cases and as shown in FIG. 2C, a thin native oxide layer 30 is formed on front surface 22 of substrate 12 during the annealing step and/or the plasma implantation step. Native oxide layer 30 can be formed by interactions between silicon atoms and oxygen atoms and/or ions exposed to front surface 22. The thickness of native oxide layer 30, for example, may be between about 10 Angstroms and about 30 Angstroms.

An etching step may be used to remove oxide layer 30, if present. FIG. 2D illustrates a cross section of substrate 12 after the etching step. Any etching technique known in the art which can sufficiently remove oxide layer 30 without damaging underlying layers may be used. Such techniques include plasma etching and wet etching. When a wet etch step is used, substrate 12 generally is transferred from the annealing apparatus (e.g., furnace) to a wet etch station. When a plasma etch step is used, substrate 12 may either be transferred to an etching chamber, or may remain in the same process chamber as used in the annealing step if etching can be performed in the process chamber. It should be understood that in some embodiments, a native oxide layer 30 may not be formed and, in other embodiments, the native oxide layer may not be removed.

The method includes an epitaxial growth step for growing an epitaxial silicon layer 32 on silicon seed layer 28 to form silicon layer 16 (FIG. 1). FIG. 2E is a cross section of substrate 12 after the epitaxial growth step. In some cases, substrate 12 may be transferred to a process chamber to grow the epitaxial layer or, the substrate can remain in a process chamber from previous steps if the chamber has epitaxial growth capabilities. A variety of epitaxial growth techniques known in the art may be used to grow epitaxial layer 32. In one exemplary technique, epitaxial layer 32 is grown using a chemical vapor deposition (CVD) technique in which substrate is heated to an elevated temperature (e.g., 700° C.) and silane (SiH₄) gas is introduced into a process chamber with the wafer at an elevated temperature. The silane gas reacts at the surface of substrate 12 to form epitaxial layer 32 on seed layer 28. The high crystal quality of seed layer 28 facilitates the deposition of epitaxial layer 32 as an epitaxial layer with a low defect concentration. If desired, epitaxial layer 32 may be n-type or p-type doped during deposition by conventional techniques.

The epitaxial growth step is performed until the desired thickness is achieved. The thickness of epitaxial layer 32 is generally sufficient to enables devices to be formed in the epitaxial layer. Epitaxial layer 32, for example, may be between about 500 Angstroms and 2000 Angstroms. However, the specific thickness of epitaxial layer 32 is dictated by the particular application. Epitaxial layer 32 preferably is a single-crystal silicon layer having a low defect concentration.

It should be understood that the method shown in FIGS. 2A-2E is illustrative of one embodiment of the present invention. The illustrative method may include several variations known to one of ordinary skill in the art.

The method shown in FIGS. 2A-2E may be used to produce an SOI wafer which may be further processed as known in the art to include semiconductor devices as desired by the particular application. Further processing can include the formation of doped regions 17 (FIG. 1) within second silicon layer 16, additional layers 18 (FIG. 1) on second silicon layer 16 (e.g., oxide layers, metallization layers), and the like. Exemplary devices include, but are not limited to, partially depleted or fully depleted CMOS devices.

Those skilled in the art would readily appreciate that all parameters listed herein are meant to be exemplary and that the actual parameters would depend upon the specific application for which the methods of the invention are used. It is, therefore, to be understood that the foregoing embodiments are presented by way of example only and that, within the scope of the appended claims and equivalents thereto the invention may be practiced otherwise than as specifically described.

What is claimed is:

1. A method of producing an SOI material comprising:
implanting oxygen in a substrate using plasma implantation to form an implanted region;
annealing the substrate to form an insulating layer comprising implanted oxygen; and
growing a silicon layer over the insulating layer to produce an SOI material.

2. The method of claim 1, wherein the silicon layer is grown epitaxially.

3. The method of claim 1, wherein the substrate is silicon.

4. The method of claim 1, wherein the insulating layer comprises silicon oxide.

5. The method of claim 1, wherein the insulating layer is formed by the reaction between implanted oxygen and the substrate.

6. The method of claim 1, comprising implanting oxygen using an implantation energy of less than about 40 kV.

7. The method of claim 1, comprising implanting oxygen using an implantation energy of less than about 30 kV.

8. The method of claim 1, wherein the implanted region has a peak oxygen concentration at a depth of between about 300 Angstroms and about 800 Angstroms.

9. The method of claim 1, wherein the insulating layer is buried within the substrate beneath a seed layer.

10. The method of claim 9, wherein the seed layer has a thickness of less than about 100 Angstroms.

11. The method of claim 9, wherein the seed layer has a thickness of between about 30 Angstroms and about 100 Angstroms.

12. The method of claim 9, wherein the seed layer is substantially free of oxygen atoms.

13. The method of claim 1, wherein the insulating layer has a thickness between about 800 Angstroms and about 2000 Angstroms.

14. The method of claim 1, wherein the silicon layer has a thickness of between about 500 Angstroms and about 2000 Angstroms.

15. The method of claim 1, further comprising removing a native oxide layer formed upon a surface of the substrate in an etching process prior to growing the silicon layer.

16. The method of claim 1, further comprising forming one or more semiconductor devices in the silicon layer.

17. A method of producing an SOI material comprising:
implanting oxygen in a substrate using plasma implantation to form an implanted region;
annealing the substrate to cause a reaction between implanted oxygen and the substrate to form an insulating layer; and
epitaxially growing a silicon layer over the insulating layer to produce an SOI material.

18. The method of claim 17, wherein the substrate is silicon.

19. The method of claim 17, wherein the insulating layer comprises silicon oxide.

20. The method of claim 17, wherein the insulating layer is buried within the substrate beneath a seed layer.
